(19) United States
(12) Patent Application Publication
(10) Pub. No.: US 2014/0175944 A1
(43) Pub. Date: Jun. 26, 2014

(54) CRYSTAL RESONATOR

(71) Applicant: NIHON DEMPA KOGYO CO., LTD., TOKYO (JP)

(72) Inventors: MITSUAKI KOYAMA, SAITAMA (JP); MANABU ISHIKAWA, SAITAMA (JP); TAKERU MUTOH, SAITAMA (JP)

(73) Assignee: NIHON DEMPA KOGYO CO., LTD., TOKYO (JP)

(21) Appl. No.: 14/139,796

(22) Filed: Dec. 23, 2013

(30) Foreign Application Priority Data
Dec. 25, 2012 (JP) 2012-281063

(51) Int. Cl. H03H 9/17

(52) U.S. Cl. CPC H03H 9/177
USPC 310/320

(57) ABSTRACT

A crystal resonator includes a mesa-type crystal element, a pair of excitation electrodes, and a deformed portion. The mesa-type crystal element has a principal surface portion and a peripheral edge portion. The peripheral edge portion surrounds the principal surface portion and has a smaller thickness than the principal surface portion. The pair of excitation electrodes are formed at the principal surface portion on one surface side and the principal surface portion on an other surface side of the crystal element, respectively. The deformed portion is configured to reduce a vibration different from a main vibration and confine energy to the principal surface portion.

### CROSS REFERENCE TO RELATED APPLICATION

This application claims the priority benefit of Japan application serial no. 2012-281063, filed on Dec. 25, 2012. The entirety of the above-mentioned patent application is hereby incorporated by reference herein and made a part of this specification.

### TECHNICAL FIELD

This disclosure relates to a crystal resonator with good vibration characteristic.

### DESCRIPTION OF THE RELATED ART

Since an AT-cut crystal resonator features excellent frequency stability with respect to temperature, the AT-cut crystal resonator is widely used in an industrial field such as information, communications, and sensor. This crystal resonator is excited in a thickness-shear vibration mode. However, advanced downsizing is prone to generate a spurious caused by face shear vibration, which is an unwanted response, and sudden fluctuation phenomenon in oscillation frequency referred to as a “dip”.

As a crystal element with energy confinement type, a convex type, a bevel type, and a mesa type are known. However, a driving surface of the crystal element needs to be a flat surface depending on an equivalent constant of an electrical equivalent circuit for the crystal resonator, and use of the convex type and the bevel type may be difficult. From this point, the inventors of this disclosure focused on a crystal element with mesa type structure. This crystal element includes a principal surface portion and a peripheral edge portion, which has a smaller thickness than the principal surface portion and surrounds the principal surface portion. This crystal element concentrates main vibration energy on the principal surface portion and confines the energy to the principal surface portion to reduce generation of the unwanted response. However, with further advanced downsized crystal element, fully reducing generation of the spurious and the dip is difficult even with the mesa-type structure. Accordingly, a configuration providing larger energy confinement effect has been examined.

Japanese Unexamined Patent Application Publication No. 2007-189414 (hereinafter referred to as Patent Literature 1) discloses a mesa-type piezoelectric vibrating piece with a thick walled portion and a thin walled portion around the thick walled portion. The piezoelectric vibrating piece has a configuration that removes an unnecessary vibration by forming a plurality of depressed parts on a plate surface of the thin walled portion. Japanese Unexamined Patent Application Publication No. 2007-208771 (hereinafter referred to as Patent Literature 2) discloses a mesa-type crystal resonator with depressed parts at peripheral edge portions of excitation electrodes in plan view. The crystal resonator has a configuration that expands a frequency pulling range by decreasing a ratio of electrostatic capacity C0 with respect to an electrical equivalent circuit capacity C1 (capacitance ratio).

However, Patent Literature 1 and Patent Literature 2 do not disclose a technique to minimize generation of a “dip”. Accordingly, it is difficult to solve the problem of this disclosure even with Patent Literature 1 and Patent Literature 2.

A need thus exists for a crystal resonator which is not susceptible to the drawback mentioned above.

### SUMMARY

A crystal resonator according to the disclosure includes a mesa-type crystal element, a pair of excitation electrodes, and a deformed portion. The mesa-type crystal element has a principal surface portion and a peripheral edge portion. The peripheral edge portion surrounds the principal surface portion and has a smaller thickness than the principal surface portion. The pair of excitation electrodes are formed at the principal surface portion on one surface side and the principal surface portion on other surface side of the crystal element, respectively. The deformed portion is configured to reduce a vibration different from a main vibration, and the deformed portion confines energy to the principal surface portion.

### BRIEF DESCRIPTION OF THE DRAWINGS

The foregoing and additional features and characteristics of this disclosure will become more apparent from the following detailed description considered with reference to the accompanying drawings, wherein:

FIG. 1 is a side view of an exemplary crystal resonator.

FIG. 2 is a plan view illustrating the crystal resonator and a characteristic diagram illustrating a relationship between an amount of displacement caused by thickness-shear vibration and a position on a crystal element.

FIG. 3 is a side view illustrating the crystal resonator and a characteristic diagram illustrating a relationship between an amount of displacement caused by oscillating wave and a position on the crystal element.

FIG. 4 is a side view of an exemplary crystal resonator of a first embodiment;

FIG. 5 is a plan view illustrating the crystal resonator.

FIG. 6 is a perspective view illustrating the crystal resonator.

FIG. 7 is a side view illustrating another exemplary crystal resonator of the first embodiment.

FIG. 8 is a plan view illustrating the crystal resonator.

FIG. 9 is a perspective view illustrating the crystal resonator.

FIG. 10 is a side view illustrating yet another exemplary crystal resonator of the first embodiment.

FIG. 11 is a plan view illustrating the crystal resonator.

FIG. 12 is a perspective view illustrating the crystal resonator.

FIG. 13 is a side view illustrating yet another exemplary crystal resonator of the first embodiment.

FIG. 14 is a plan view illustrating the crystal resonator.

FIG. 15 is a perspective view illustrating an exemplary extruding part disposed at the crystal element.

FIG. 16 is a perspective view illustrating an exemplary extruding part disposed at the crystal element.

FIG. 17 is a perspective view illustrating an exemplary extruding part disposed at the crystal element.

FIG. 18 is a perspective view illustrating an exemplary extruding part disposed at the crystal element.

FIG. 19 is a side view of an exemplary crystal resonator of a second embodiment.

FIG. 20 is a plan view illustrating the crystal resonator.

FIG. 21 is a perspective view illustrating the crystal resonator.

FIG. 22 is a side view illustrating another exemplary crystal resonator of the second embodiment.

FIG. 23 is a plan view illustrating the crystal resonator.

FIG. 24 is a side view illustrating yet another exemplary crystal resonator of the second embodiment.

FIG. 25 is a side view illustrating yet another exemplary crystal resonator of the second embodiment.

FIG. 26 is a longitudinal cross-sectional side view illustrating an exemplary electronic component including the crystal resonator.

FIG. 27 is a side view illustrating yet another exemplary crystal resonator.

FIG. 28 is a plan view illustrating the crystal resonator.

FIG. 29 is a characteristic diagram illustrating a result of working example.

FIG. 30 is a characteristic diagram illustrating a result of the working example.

### DETAILED DESCRIPTION

### First Embodiment

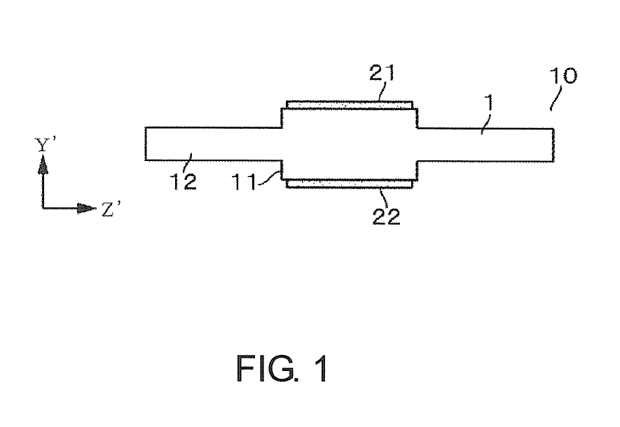

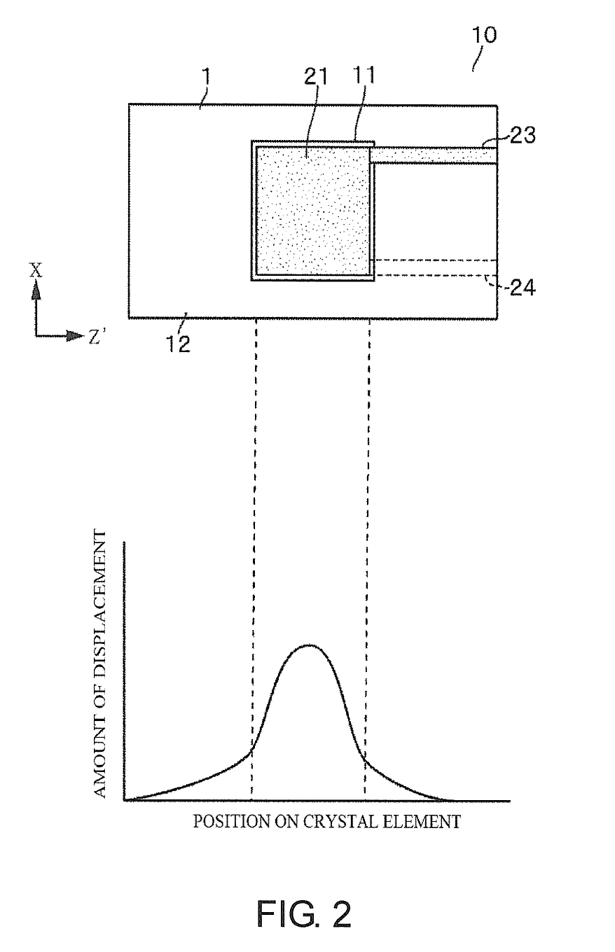

An outline of a crystal resonator of a first embodiment of this disclosure will be described by referring to FIG. 1 to FIG. 3. First, a basic configuration of a mesa-type crystal resonator 10 of this disclosure will be described based on FIG. 1 and FIG. 2. Reference numeral “1” in FIG. 1 and FIG. 2 denotes a mesa-type AT-cut crystal element 1 with a principal surface portion 11 and a peripheral edge portion 12. The peripheral edge portion 12 surrounds the principal surface portion 11 and has smaller thickness than the principal surface portion 11. In this example, the principal surface portion 11 has, for example, a planar square shape, and the peripheral edge portion 12 has a planar rectangular shape. The following describes the longitudinal direction of the peripheral edge portion 12 as Z′ direction while the short side direction of the peripheral edge portion 12 as X direction.

The crystal element 1 includes a first excitation electrode 21 at the principal surface portion 11 on one surface side. The crystal element 1 includes a second excitation electrode 22 at the principal surface portion 11 on the other surface side. These first and second excitation electrodes 21 and 22 are configured to have a mutually same shape and are opposed via the principal surface portion 11. The first and the second excitation electrodes 21 and 22, for example, are formed to be a rectangular shape almost same as or slightly small than the principal surface portion 11. Reference numeral “23” in the drawing denotes an extraction electrode of the first excitation electrode 21, and reference numeral “24” denotes an extraction electrode of the second excitation electrode 22. These extraction electrodes 23 and 24 are extended to end regions of the crystal element 1. Thus, the crystal resonator 10 is constituted with the crystal element 1 and the first and second excitation electrodes 21 and 22.

The AT-cut crystal resonator 10 is mainly vibrated at the thickness-shear vibration; however, an unwanted response, face shear vibration, is generated. FIG. 2 shows a relationship between an amount of displacement caused by thickness-shear vibration and a position of the thickness-shear vibration in the longitudinal direction of the crystal element 1. As illustrated, the amount of displacement of the main vibration becomes large near the excitation electrodes 21 and 22.

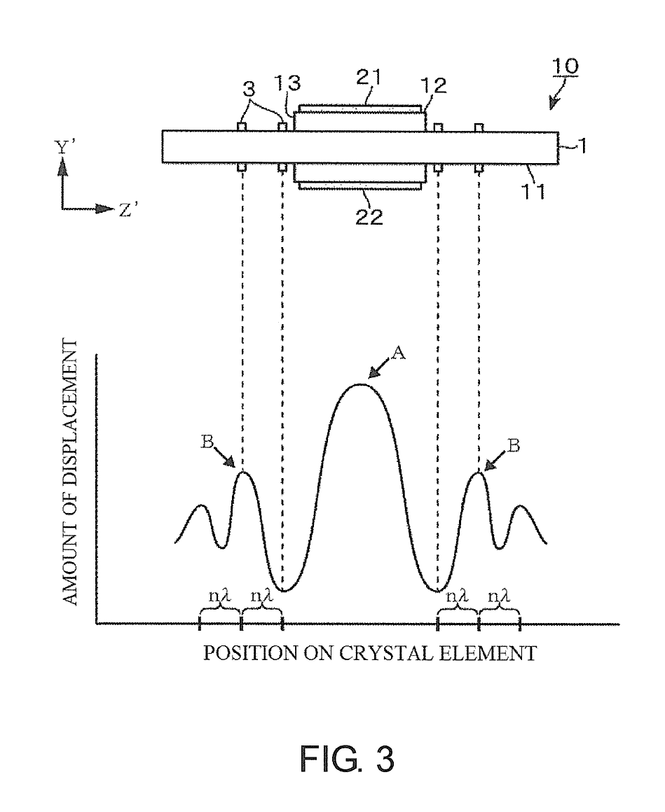

In this embodiment, to reduce a vibration different from the main vibration and confine energy to the principal surface portion, the crystal element 1 includes at least one of the extruding part and the depressed part. This extruding part and the depressed part are disposed at least one of the principal surface portion 11 on the one surface side and the principal surface portion 11 on the other surface side. The extruding part and the depressed part are disposed near a boundary between the principal surface portion 11 and the peripheral edge portion 12 across the whole circumference so as to surround the excitation electrodes 21 and 22. The extruding part and the depressed part are described with an exemplary arrangement of an extruding part 3 illustrated in FIG. 3. FIG. 3 schematically shows an oscillating wave excited at the crystal resonator 10. The vertical axis indicates an amount of displacement and the horizontal axis indicates the longitudinal direction position of the crystal element 1. In FIG. 3, reference symbol “A” denotes a peak caused by the main vibration (thickness-shear vibration), while reference symbol “B” denotes a peak caused by unwanted response (face shear vibration).

The extruding part and the depressed part achieve the same role as a tetrapod installed at a breakwater at a coast, for example. That is, when oscillating wave and reflected wave excited at the crystal resonator 10 transmits to a region with the extruding part or the depressed part, since the surface of the region is rough, the propagation direction changes, causing diffused reflection. Then, the oscillating waves about to propagate act on one another and then is gradually damped, resulting in dissipation. Therefore, disposing the extruding part or the depressed part at the crystal element 1 absorbs energy of the oscillating wave and the reflected wave.

The vibration different from the main vibration is face shear vibration, which is an unwanted response. With the mesa-type crystal element 1, displacement of vibration of face shear vibration is small at the center portion of the principal surface portion 11 and large at the outer edge of the principal surface portion 11. Therefore, disposing the extruding part or the depressed part near the boundary between the principal surface portion 11 and the peripheral edge portion 12 absorbs energy caused by the face shear vibration, reducing generation of an unwanted response and also reducing influence from the reflected wave. Since the extruding part or the depressed part is disposed across the whole circumference of the peripheral area of the excitation electrodes 21 and 22, a degree of attenuation of the unwanted response can be made uniform in the circumferential direction of the excitation electrodes 21 and 22. This reduces vibration energy leaked from the excitation electrodes 21 and 22, which are different from the main vibration. This enhances energy confinement effect of the main vibration, ensuring good vibration characteristic. That is, this allows recuing generation of a spurious caused by the face shear vibration and generation of a dip caused by joining of thickness-shear vibration mode and face shear vibration. Therefore, disposing the extruding part and the depressed part at the crystal element reduces a vibration different from the main vibration and confines energy to the principal surface portion, and thus provides good vibration characteristic.

It is preferred that the extruding parts 3 and the depressed parts be disposed at valleys between the peak A and the peak B of the oscillating wave and near the peak B position of the unwanted response as shown in FIG. 3. However, the inventors consider that disposing the extruding part 3 and the depressed part near the boundary between the principal surface portion 11 and the peripheral edge portion 12 allows reducing the face shear vibration. Near the boundary between the principal surface portion 11 and the peripheral edge portion 12 means that, the regions outside of the excitation electrodes 21 and 22 on the principal surface portion 11, a sidewall portion 13 of the principal surface portion 11, and near the sidewall portion 13 of the principal surface portion 11 at the peripheral edge portion 12. Further, the extruding part and the depressed part may be disposed at one of one surface side and the other surface side of the crystal element 1.

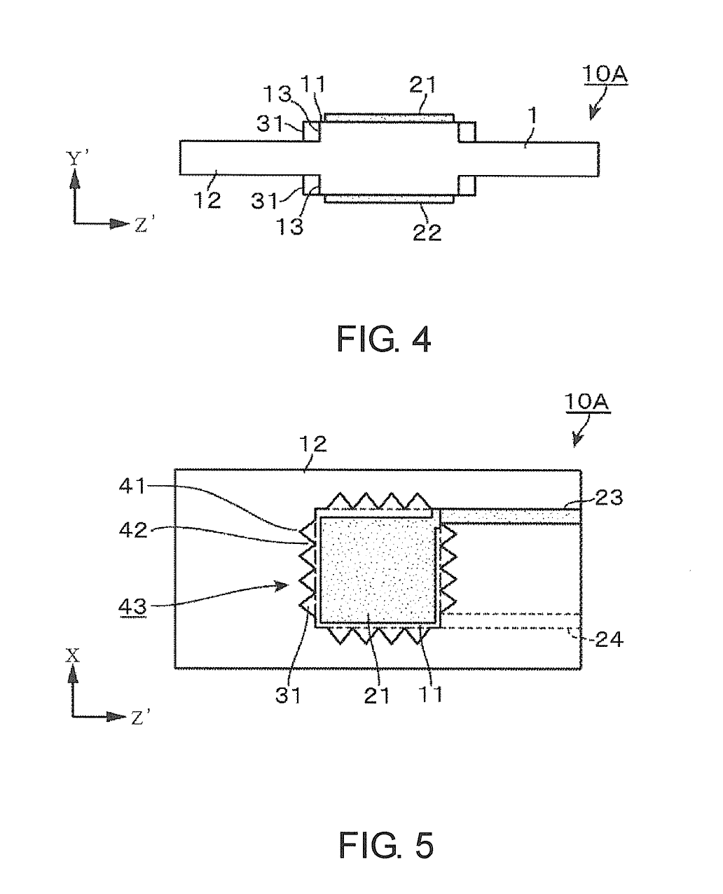

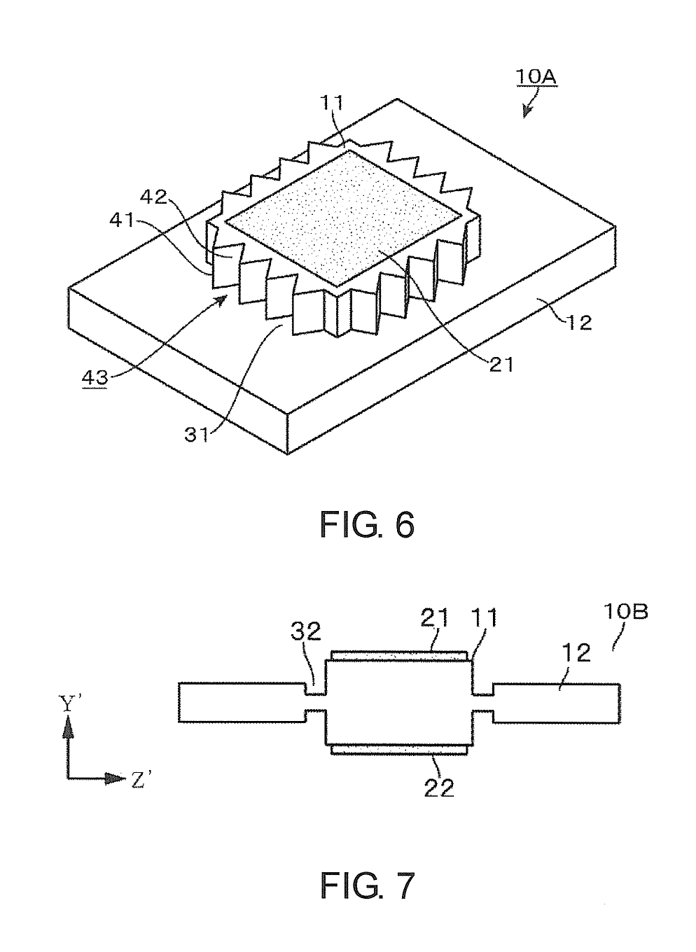

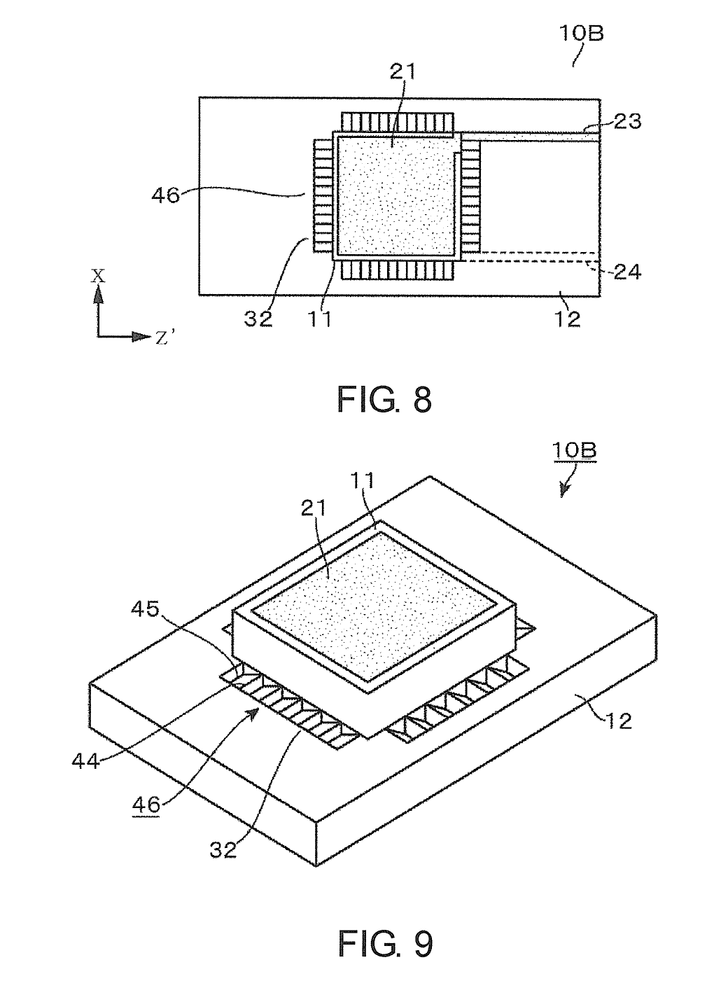

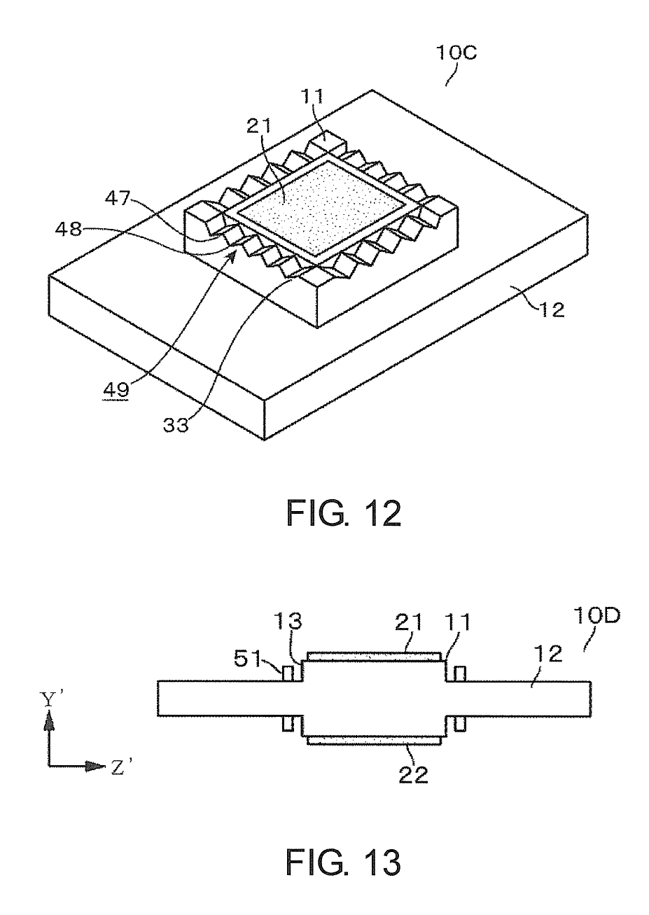

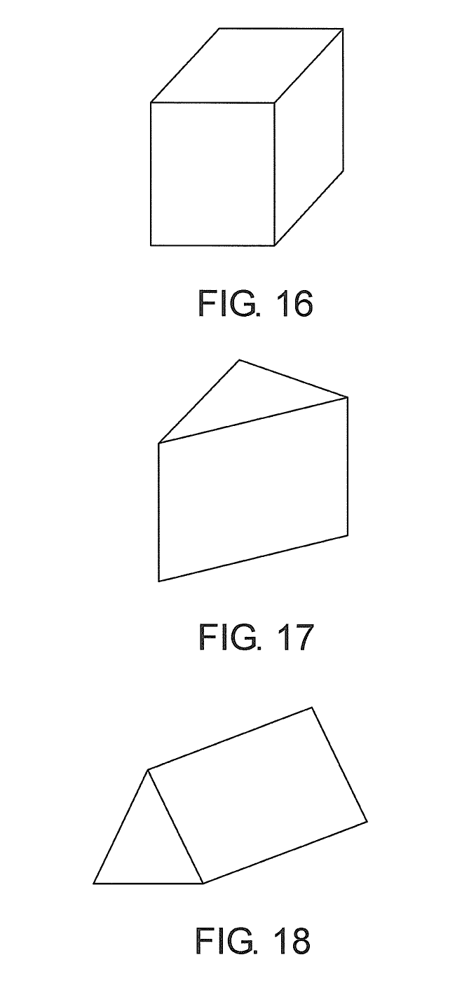

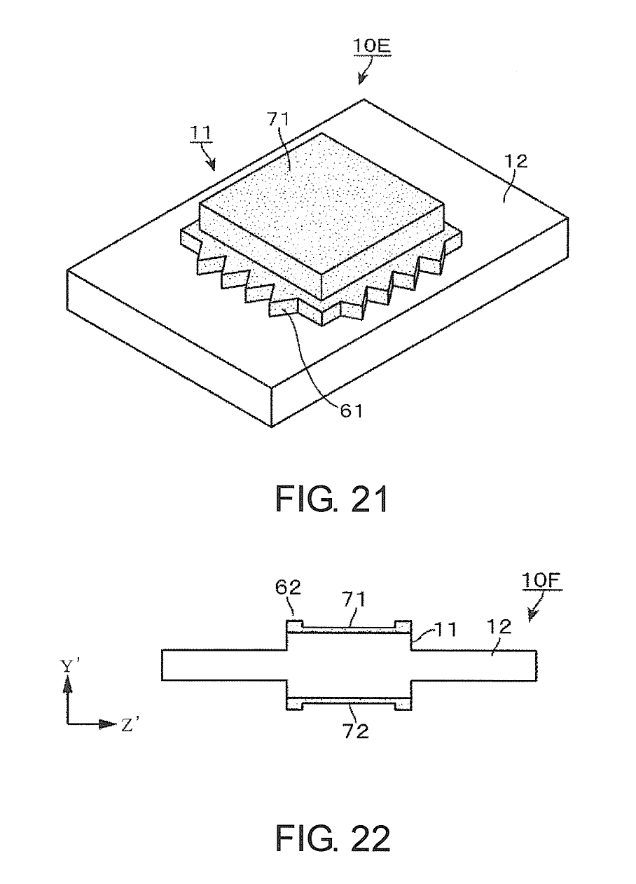

Subsequently, the configurations of the extruding part and the depressed part disposed at the crystal resonator 10 will be specifically described with reference to FIG. 4 to FIG. 18. However, like reference numerals designate corresponding or identical elements throughout the crystal resonator 10 in FIG. 1 and FIG. 2 and FIG. 4 to FIG. 18, and therefore such elements will not be further elaborated here. A crystal resonator 10A shown in FIG. 4 to FIG. 6 is an example where an extruding part 31 is disposed at the principal surface portion 11. FIG. 5 shows the region corresponding to the principal surface portion 11 in FIG. 1 and FIG. 2 by one dot chain lines. FIG. 6 omits extraction electrodes 23 and 24 (FIG. 9, FIG. 12, and FIG. 21 similarly omit extraction electrodes).

The exemplary crystal resonator 10A includes the extruding part 31 with triangular prism shape across the whole circumference of the sidewall portion 13 of the principal surface portion 11. In view of this, as the crystal element 1 is planarly viewed, a wavelike-region 43 is formed at the edge (outer edge) portion of the principal surface portion 11. At the wavelike-region 43, an extruding section 41 and a depressed section 42 are alternately arranged with one another. In this example, the wavelike-region 43 is constituted to have a saw tooth shape in plane view. In plane view, the wavelike-region 43 is formed so that any region between the outer end of the extruding section 41 (end on the peripheral edge portion side) and the inner end of the depressed section 42 (end on the principal surface portion side) may be within between the peak A of the main vibration and the peak B of the unwanted response as shown in FIG. 3, for example.

In the configuration, the wavelike-region 43 is formed at the sidewall portion 13 of the principal surface portion 11. The crystal element 1 forms unevenness at the boundary between the principal surface portion 11 and the peripheral edge portion 12 so as to surround the excitation electrodes 21 and 22. Since this wavelike-region 43 absorbs energy of unwanted response and reflected wave as described above, confinement effect of the main vibration energy becomes high at the principal surface portion 11. A period of wave surfaces on the saw tooth-shaped wavelike-region 43 is equalized to the periods of face shear vibration and excellent harmonics, which differently vibrate from the main vibration, thus driving of the vibration different from the main vibration can be reduced. Alternatively, the period of the wave surfaces may be equalized to the period of the thickness-shear vibration, which is the main vibration, to confine energy to the principal surface portion 11. Furthermore, the period of the wave surfaces may not be equalized to the period of the thickness-shear vibration, which is the main vibration, and energy of the unwanted response may be emitted from the principal surface portion 11 to attenuate the energy of the unwanted response using diffused reflection generated by the unevenness. Here, the description is given with the configuration where the extruding part 31 is disposed at the sidewall portion 13 of the principal surface portion 11 and the wavelike-region 43 is formed at the extruding part 31. However, a depressed part may be formed at the sidewall portion 13 and the wavelike-region may be formed at the depressed part, or the extruding part and the depressed part may be formed at the sidewall portion 13 and the wavelike-regions may be formed at the extruding part and the depressed part.

A crystal resonator 10B shown in FIG. 7 to FIG. 9 is an exemplary formation of a depressed part 32 near the sidewall portion 13 of the principal surface portion 11 at the peripheral edge portion 12 across the whole circumference of the principal surface portion 11. The depressed part 32 is formed with its cross-sectional configuration when sliced thickness-wise through the peripheral edge portion 12 formed into to a triangular geometry in which the vertices point downward. Accordingly, as viewing the surface cut taken along the thickness direction of the crystal element 1, a saw tooth-shaped wavelike-region 46 is formed near the outer edge (edge) of the principal surface portion 11. At the wavelike-region 46, an extruding section 44 and a depressed section 45 are alternately arranged with one another. The wavelike-region 46 is formed such that at least a part of the wavelike-region 46 may be positioned between peak A of the main vibration and peak B of the unwanted response of the oscillating wave shown in FIG. 3, for example.

In the configuration, the wavelike-region 46 is formed near the principal surface portion 11 at the peripheral edge portion 12. The crystal element 1 forms unevenness at the boundary between the principal surface portion 11 and the peripheral edge portion 12 so as to surround the excitation electrodes 21 and 22. Since this wavelike-region 46 absorbs energy of unwanted response and reflected wave as described above, confinement effect of the main vibration energy becomes high at the principal surface portion 11.

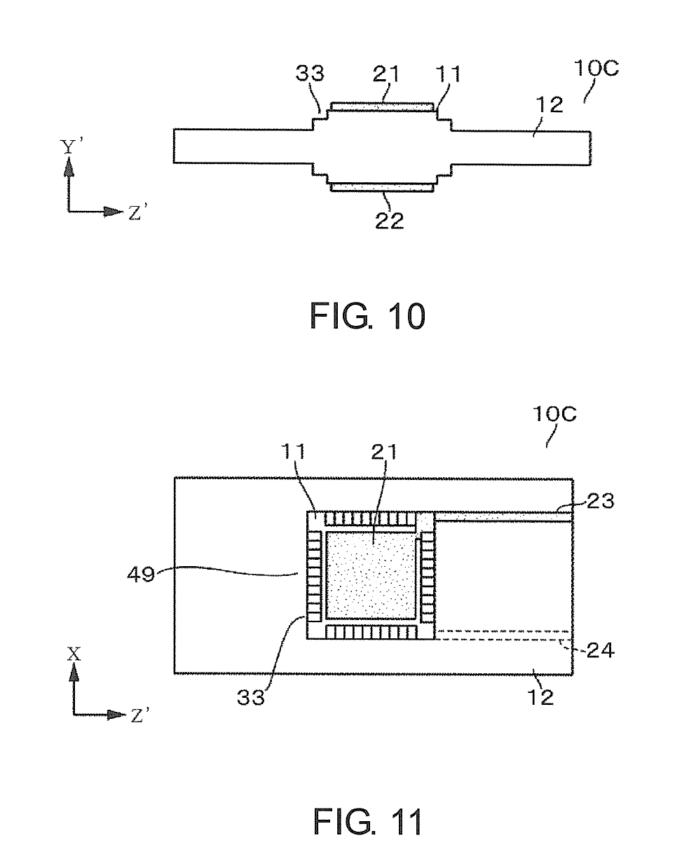

Additionally, the crystal resonator in FIG. 10 to FIG. 12 shows an example where a depressed part 33 is formed at the outside of the excitation electrodes 21 and 22 at the principal surface portion 11. In this the example, the depressed part 33 is disposed near the outer edge of the principal surface portion 11 across the whole circumference of the principal surface portion 11. The depressed part 33 is formed with its cross-sectional configuration when sliced thickness-wise through the principal surface portion 11, for example, formed into to a triangular geometry in which the vertices point downward. Accordingly, as viewing the surface cut taken along the thickness direction of the crystal element 1, a saw tooth-shaped wavelike-region 49 is formed near the outer edge of the principal surface portion 11. At the wavelike-region 49, an extruding section 47 and a depressed section 48 are alternately arranged with one another. The wavelike-region 49 is formed such that at least a part of the wavelike-region 49 may be positioned between peak A of the main vibration and peak B of the unwanted response of the oscillating wave shown in FIG. 3, for example. Insofar as the property is not affected, the wavelike-regions 49 may partially exist at the formation regions of the excitation electrodes 21 and 22.

With the configuration, the wavelike-region 49 is formed at the edge of the principal surface portion 11; therefore, the crystal element 1 includes unevenness that surrounds the excitation electrodes 21 and 22 at the boundary between the principal surface portion 11 and the peripheral edge portion 12. Since this wavelike-region 49 absorbs energy of unwanted response and reflected wave as described above, confinement effect of the main vibration energy becomes high at the principal surface portion 11. In the crystal resonator 10B shown in FIG. 7 to FIG. 9 and a crystal resonator 10C shown in FIG. 10 to FIG. 12, periods of wave surfaces on the saw tooth-shaped wavelike-regions 46 and 49 are equalized to the periods of face shear vibration and higher harmonics, which differently vibrate from the main vibration, thus driving of the vibration different from the main vibration can be reduced. Alternatively, the period of the wave surfaces may be equalized to the period of the thickness-shear vibration, which is the main vibration, to confine energy to the principal surface portion 11. Furthermore, the period of the wave surfaces may not be equalized to the period of the thickness-shear vibration, which is the main vibration, and energy of the unwanted response may be emitted from the principal surface portion 11 to attenuate the energy of the unwanted response using diffused reflection generated by the unevenness.

In the crystal resonator 10B shown in FIG. 7 to FIG. 9 and the crystal resonator 10C shown in FIG. 10 to FIG. 12, the extruding parts may be formed at the principal surface portion 11 and the peripheral edge portion 12 and the wavelike-regions may be formed at the extruding parts, or the extruding part and the depressed part may be formed at the principal surface portion 11 and the peripheral edge portion 12 and the wavelike-regions may be formed at the extruding part and the depressed part.

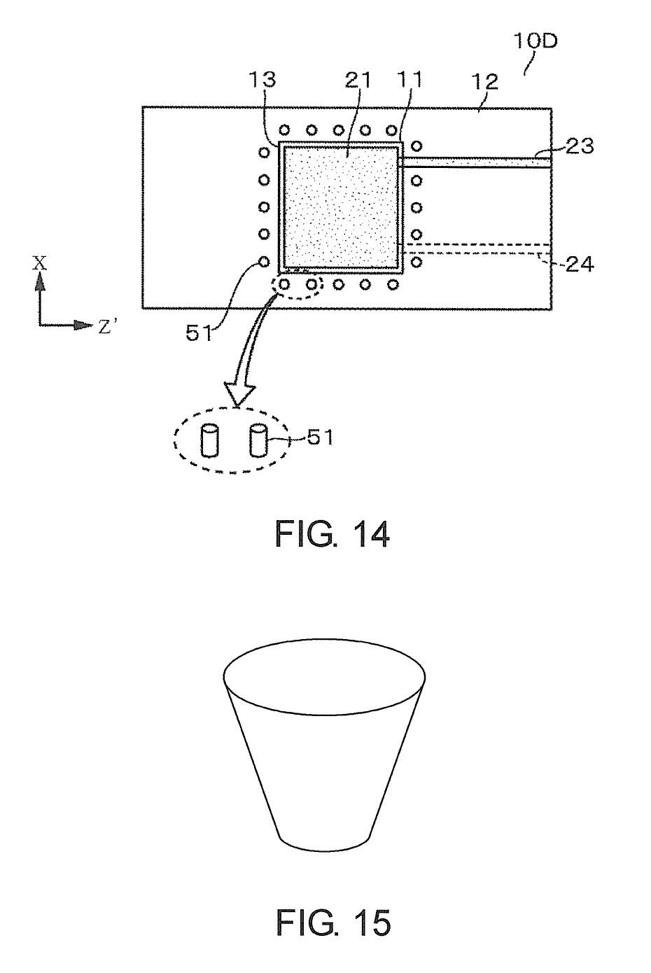

A crystal resonator 10D in FIG. 13 and FIG. 14 shows an example of disposing a protrusion 51 forming an extruding part at the peripheral edge portion 12. A large number of the protrusions 51 are formed at the peripheral edge portion 12 near the sidewall portion 13 of the principal surface portion 11 with mutually spaced across the whole circumference of the principal surface portion 11. This protrusion 51 is, for example, constituted to have a columnar shape, a conical shape, a quadrangular prism shape, and a triangular prism shape as shown in FIG. 15 to FIG. 18. The protrusion 51 is formed so as to be positioned between peak A of the main vibration and the peak B of the unwanted response of the oscillating wave shown in FIG. 3, for example.

With the configuration, the protrusions 51 are disposed at the boundary between the peripheral edge portion 12 and the principal surface portion 11 so as to surround the excitation electrodes 21 and 22. Since unevenness formed by the protrusions 51 absorbs energy of unwanted response and reflected wave, confinement effect of the main vibration energy becomes high at the principal surface portion 11. The protrusion 51 may be disposed not only at the peripheral edge portion 12 but also be disposed at the sidewall portion 13 of the principal surface portion 11 and near the edge of the principal surface portion 11. As shown in FIG. 3, the protrusion 51 may be arranged so as to doubly or triply surround the excitation electrodes 21 and 22.

Then, a method for fabricating the crystal resonators 10A to 10D shown in FIG. 4 to FIG. 14 will be briefly described. First, one piece of cutout quartz substrate, for example, a quartz-crystal wafer is polished and cleaned. Then, regions other than the principal surface portion 11 are dug down by etching, thus forming a mesa structure. This etching is wet etching or dry etching. In formation by wet etching, metal films are formed on both surfaces of the quartz substrate, for example, positive resist film are formed on the metal films. Next, predetermined patterns are exposed on the positive resist films, the positive resist films are developed, dipped in potassium iodide (KI) solution, and metal-etched, thus mask patterns with laminated metal films and resist films are formed. Next, the quartz substrate with the mask patterns formed on the surfaces is etched by being dipped into a hydrogen fluoride solution to form the mesa structure on the quartz substrate.

In formation by dry etching, a mask pattern is formed on the surface of the quartz substrate by a similar method to the above-described wet etching, for example. Next, the quartz substrate with the mask pattern formed on the surface is etched, for example, using etching gas such as CHF₃ gas, thus the mesa structure is formed on the quartz substrate.

Next, a metal film formed by laminating Au on Cr, for example, is formed on the quartz substrate by, for example, sputtering and vacuum deposition method. After the resist pattern is formed on the metal film, the quartz substrate is dipped into the KI solution to form an electrode pattern. After that, the quartz substrate is cut along a dicing line using a dicing saw, and the crystal resonator is cut and divided one by one from the quartz substrate, thus the crystal resonators are completed.

### Second Embodiment

In this embodiment, an extruding part is formed across the whole circumference of at least one of the outer edges of the excitation electrode 21, which is on one surface side of the crystal element 1, and the excitation electrode 22, which is on the other surface side of the crystal element 1. The extruding part is covered with an electrode film constituting the excitation electrodes 21 and 22. When the oscillating wave and the reflected wave excited at the crystal resonator are attempted to transmit to the region with the extruding part, the oscillating wave and the reflected wave cause diffused reflection. Therefore, the oscillating waves, which attempt to propagate, act with one another, and the oscillating wave and the reflected wave gradually attenuate, thus reducing generation of the unwanted response. The excitation electrodes 21 and 22 are formed larger than the principal surface portion 11. This coats the excitation electrodes 21 and 22 up to the unwanted-response-generating region with electrode films. In view of this, viscosity of the electrode film makes transmission of the unwanted response difficult, resulting in reduction in generation of the unwanted response. Furthermore, the extruding part is disposed at the outer edge of the excitation electrode 21 (22) across the whole circumference. Accordingly, a level of attenuation of the unwanted response is equalized in the circumferential direction of the excitation electrode 21 (22). Therefore, disposing the extruding part at the crystal element reduces a vibration different from the main vibration, confines energy to the principal surface portion, and thus for providing good vibration characteristic.

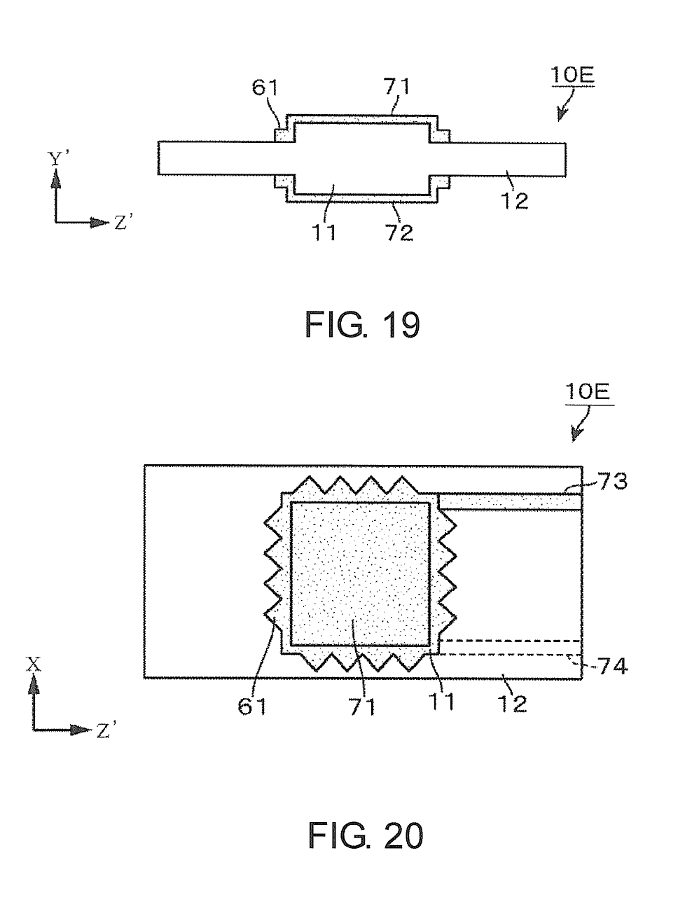

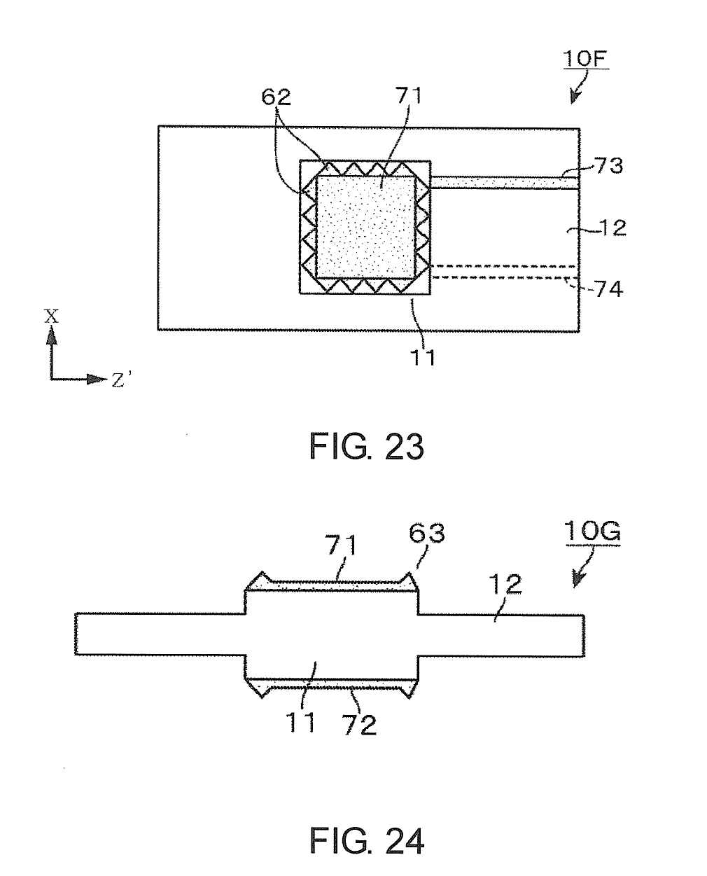

A crystal resonator 10E shown in FIG. 19 to FIG. 21 includes an excitation electrode 71 on one surface side and an excitation electrode 72 on the other surface side of the principal surface portion 11. The excitation electrode 71 and the excitation electrode 72 coat the sidewall portion 13 from the surface portion of the principal surface portion 11, and the outer edges of the excitation electrode 71 and the excitation electrode 72 are positioned at the peripheral edge portion 12 near the sidewall portion 13 of the principal surface portion 11. In FIG. 20, reference numeral “73” denotes an extraction electrode for the excitation electrode 71 on one surface side, while reference numeral “74” denotes an extraction electrode for the excitation electrode 72 on the other surface side. Then, extruding parts 61, which are covered with electrode films constituting the excitation electrodes, are formed at the outer edges of the excitation electrode 71 on one surface side and the excitation electrode 72 on the other surface side across the whole circumference. The extruding part 61 is disposed at the peripheral edge portion 12 near the principal surface portion 11. The extruding part 61 is formed, for example, by laminating electrode films constituting the excitation electrodes 21 and 22. As planarly viewing the extruding part 61, the outer edge of the extruding part 61 is formed to be wavelike. However, the extruding part 61 may be made of crystal and the surface of the extruding part 61 may be coated with electrode film In a crystal resonator 10F shown in FIG. 22 and FIG. 23, the excitation electrodes 71 and 72 are formed only on the surface portion of the principal surface portion 11. The crystal resonator 10F includes an extruding part 62 across the whole circumference at the outer edge of the excitation electrodes 71 and 72. Therefore, the extruding part 62 is disposed near the outer edge of the principal surface portion 11. As planarly viewing the extruding part 62, the outer edge of the extruding part 62 is formed to be wavelike. This extruding part 62 may be formed by laminating electrode films constituting the excitation electrodes 21 and 22, for example. The extruding part 62 may include an extruded-shaped part made of crystal and the surface of the extruded-shaped part may be coated with the electrode films.

The extruding part 61 shown in FIG. 19 to FIG. 21 and the extruding part 62 shown in FIG. 23 have an outer edge with wavelike saw tooth shape. The period of the wave surfaces is equalized to the periods of face shear vibration and higher harmonics, which differently vibrate from the main vibration, thus driving of the vibration different from the main vibration can be reduced. Alternatively, the period of the wave surfaces may be equalized to the period of the thickness-shear vibration, which is the main vibration, to confine energy to the principal surface portion 11. Furthermore, the period of the wave surfaces may not be equalized to the period of the thickness-shear vibration, which is the main vibration, and energy of the unwanted response may be emitted from the principal surface portion 11 to attenuate the energy of the unwanted response using diffused reflection generated by the unevenness.

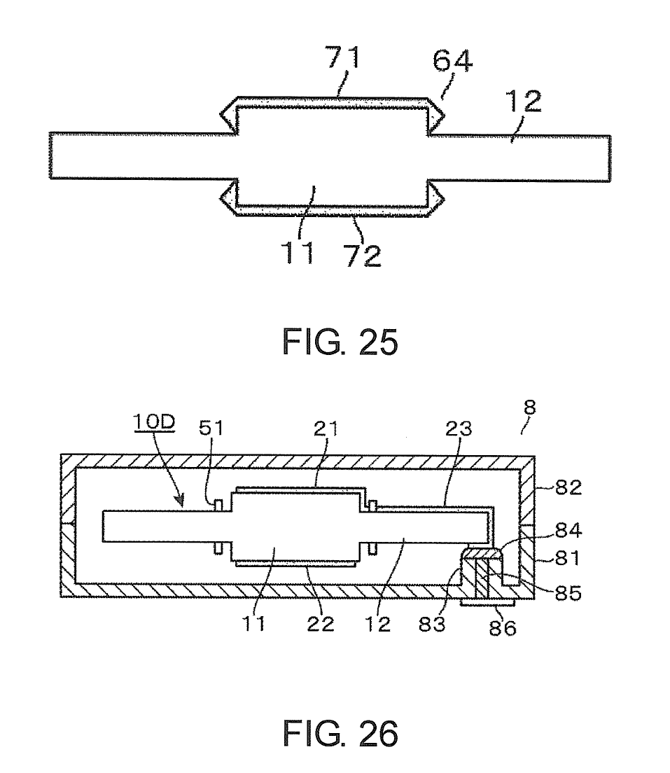

Further, as a crystal resonator 10G shown in FIG. 24, the cross section of an extruding part 63 where the extruding part 63 is cut along the thickness direction of the crystal element 1 may be approximately triangle. Further, as a crystal resonator 10H shown in FIG. 25, an extruding part 64 may be positioned at the sidewall portion 13 of the principal surface portion 11.

In the crystal resonators 10E to 10H shown in FIG. 19 to FIG. 25, the extruding part may be only necessary to cause diffused reflection of the oscillating wave and the reflected wave, and therefore the shape of the extruding part is not limited to the above-described examples. The extruding part is only necessary to be formed at least one of the outer edges of the excitation electrode 21 on one surface side and the excitation electrode 22 on the other surface side of the crystal element 1. Furthermore, the extruding part formed at the excitation electrode 21 and the extruding part formed at the excitation electrode 22 may be configured mutually different in shape and arrangement part. This is because if the extruding part causes diffused reflection of the oscillating wave and the reflected wave, the oscillating wave and the reflected wave are diffused, resulting in attenuation.

Subsequently, the electronic component incorporating the above-described crystal resonator will be described with reference to FIG. 26 in the case where the crystal resonator 10D shown in FIG. 13 is disposed as an example. In FIG. 26, reference numeral “8” denotes a package in which the crystal resonator is housed. The package 8 includes a ceramics base body 81 and a metallic lid body 82, for example. The base body 81 and the lid body 82 are seam-welded with a sealing material, formed of, for example, welding material and the insides of the base body 81 and the lid body 82 are in a vacuum state. The base body 81 includes a pedestal portion 83 to support the peripheral edge portion 12 of the crystal element 1. The peripheral edge portion 12 is secured to the pedestal portion 83 with a conductive adhesive 84. The extraction electrodes 23 and 24 are connected to respective external electrodes 86 and 86 (one side is not shown) via conductive paths 85 and 85 (one side is not shown). The conductive paths 85 and 85 are individually disposed at the respective pedestal portion 83 and the base body 81. The external electrodes 86 and 86 are individually disposed at the bottom surface of the base body 81. Mounting the electronic component and a circuit component of an oscillator circuit to a wiring board, for example, constitutes a crystal controlled oscillator.

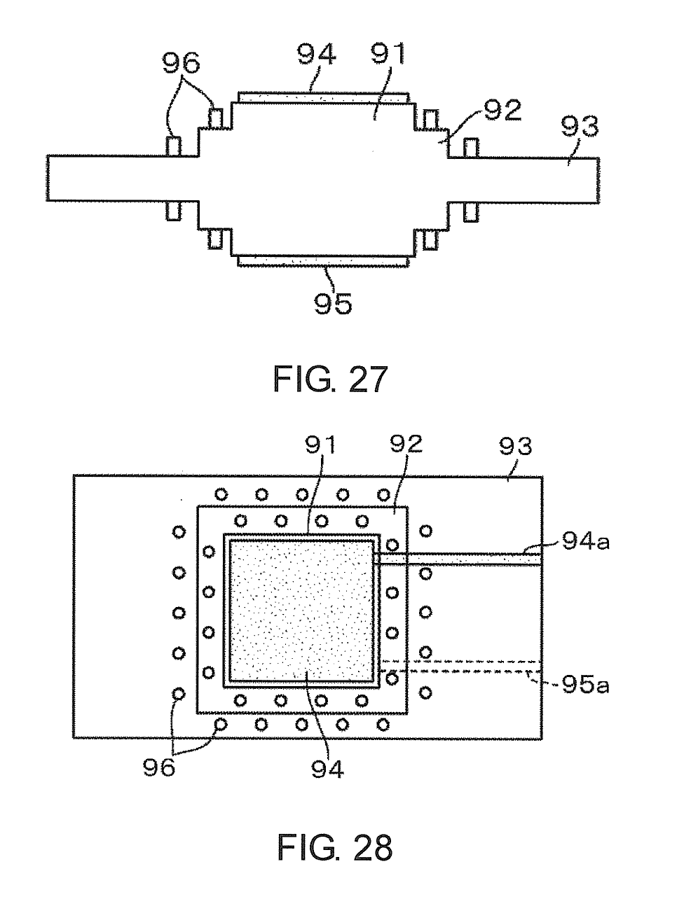

As described above, as shown in FIG. 27 and FIG. 28, the crystal resonator of this disclosure may be a mesa-type structure that includes a principal surface portion 91, an intermediate portion 92, and a peripheral edge portion 93. The intermediate portion 92 surrounds the principal surface portion 91 and has a smaller thickness than the principal surface portion 91. The peripheral edge portion 93 surrounds the intermediate portion 92 and has a smaller thickness than the intermediate portion 92. Reference numerals “94” and “95” denote excitation electrodes, and reference numerals “94a” and “95a” denote extraction electrodes. FIG. 27 and FIG. 28 show an example where column-shaped crystal extruding parts (protrusions) 96 are disposed at the intermediate portion 92 and the peripheral edge portion 93. However, the extruding part 96 and the depressed part may be formed at any position insofar as being disposed across the whole circumference so as to surround the excitation electrodes 21 and 22. It is only necessary that the extruding part 96 and the depressed part are disposed at least one of one surface side and the other surface side of the crystal element.

In the first embodiment of this disclosure, the extruding part and the depressed part are disposed at the crystal element so as to reduce a vibration different from the main vibration and to confine energy to the principal surface portion. In view of this, the extruding part and the depressed part are disposed across the whole circumference so as to surround the excitation electrode near the boundary between the principal surface portion and the peripheral edge portion at least one of the principal surface portion of the one surface side and the principal surface portion on the other surface side. The shapes and the arrangement positions of the extruding part and the depressed part can be appropriately selected insofar as the object is achieved. One of the extruding part and the depressed part may be disposed at one of one surface side and the other surface side of the crystal element, for example. The above-described extruding part 31, the depressed parts 32 and 33, and the protrusion 51 may be combined or the extruding part or the depressed part may be disposed at the respective principal surface portion and peripheral edge portion. Furthermore, the extruding part or the depressed part disposed at one surface side of the crystal element may have a mutually different shape from the extruding part or the depressed part disposed at the other surface side of the crystal element and not necessary limited to the case where the extruding part and the depressed part are opposed via the crystal element. Similarly, in the second embodiment of this disclosure, the extruding part is disposed at the outer edge of the excitation electrode to reduce a vibration different from the main vibration and to confine energy to the principal surface portion. In view of this, insofar as the extruding part is disposed at an outer edge of the excitation electrode at least one of the principal surface portion of the one surface side and the principal surface portion on the other surface side across the whole circumference, and the object is achieved, the shape and the arrangement position of the extruding part can be appropriately selected. The plurality of above-described extruding parts 61 to 64 may be combined, for example.

In the case where a wavelike-region is formed by forming the extruding part and the depressed part at the crystal element and in the case where the outer edge of the excitation electrode is formed to be wavelike, “wavelike” may be a saw tooth shape or may be a curved line. The wavelike extruding shape section and depressed shape section may not be continuously connected to one another. The region between the extruding shape section (or depressed shape section) and the neighboring extruding shape section (or depressed shape section) may be approximately flat, for example.

Accordingly, the first embodiment includes at least one of an extruding part and a depressed part disposed at the crystal element. The extruding part and the depressed part are disposed near a boundary between the principal surface portion and the peripheral edge portion disposed at least one side of the principal surface portion on the one surface side and the principal surface portion on the other surface side. The extruding part and the depressed part are disposed across a whole circumference so as to surround an excitation electrode. Meanwhile, the second embodiment includes an extruding part disposed at an outer edge across a whole circumference of at least one of the excitation electrode on the one surface side and the excitation electrode on the other surface side of the crystal element. The extruding part is covered with an electrode film constituting the excitation electrode. It is only necessary that the present disclosure includes a deformed portion configured to reduce a vibration different from a main vibration and confine energy to the principal surface portion using an unevenness part, namely, a deformed part.

### Working Example

The mesa-type crystal resonator with the configuration shown in FIG. 27 was formed by etching an AT-cut crystal element, and generation of a dip was validated. The peripheral edge portion was formed to have a rectangular shape with a longitudinal direction (Z′ direction) of 5 mm and the short side direction (X direction) of 2.5 mm. The principal surface portion was formed to have a square shape with the Z′ direction and the X direction of 1.0 mm, respectively. A distance between the surface portion of the principal surface portion and the surface portion of the intermediate portion was set approximately 3 μm, and a distance between the surface portion of the intermediate portion and the surface portion of the peripheral edge portion was set approximately 3 μm, respectively. Then, the extruding part with the shape shown in FIG. 6 was formed at the sidewall portion of the principal surface portion by etching so as to form a wavelike-region at the peripheral edge of the principal surface portion in plan view. The excitation electrode was constituted of laminated films of a Cr film and an Au film. The size of the excitation electrode was set to 1.0 mm×1.0 mm, similarly to the principal surface portion, and the thickness of 100 nm.

The validation for dip was carried out by measuring temperature characteristics of a series resonance frequency and a motional resistance applying π circuit method. Changes in the series resonance frequency and the motional resistance with respect to temperature were measured. Variation of these data means occurrence of a dip. Requirements in measurement were set as follows: temperature range of −40° C. to +125° C., a temperature step of 2.5° C., and a driving current of 2 mA±10%, so as to emphasize generation of a dip.

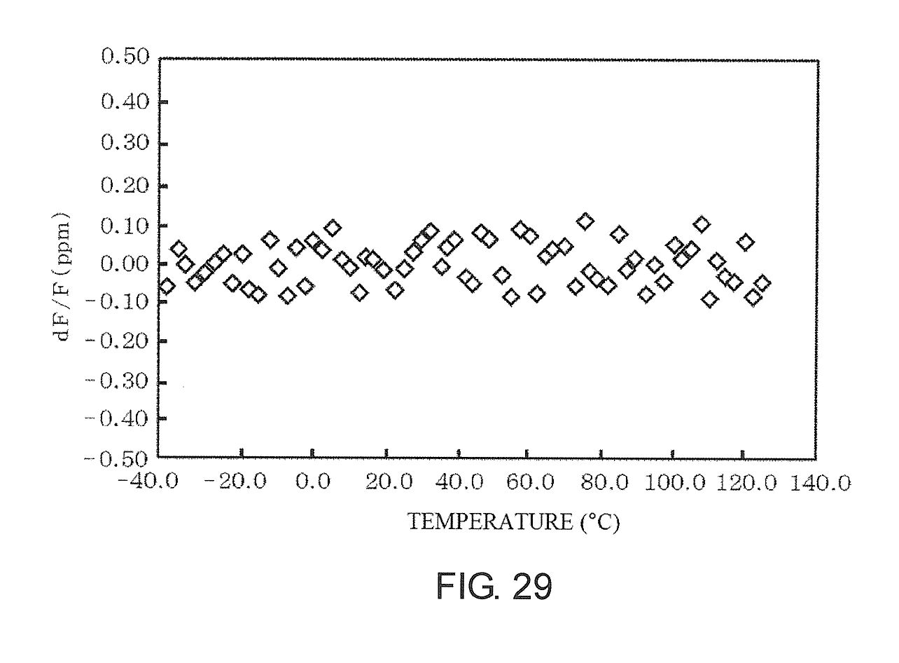

The measurement results of the temperature characteristics of the series resonance frequency are shown in FIG. 29. FIG. 29 is a graph where quartic regression analysis is performed on measurement data of a series resonance frequency and a difference between an regression equation obtained by the quartic regression analysis and the measured value (dF/F) is plotted. In the drawing, the horizontal axis indicates a temperature and the vertical axis indicates the difference. Consequently, a rapid frequency change was not confirmed and a generation of a dip was not observed.

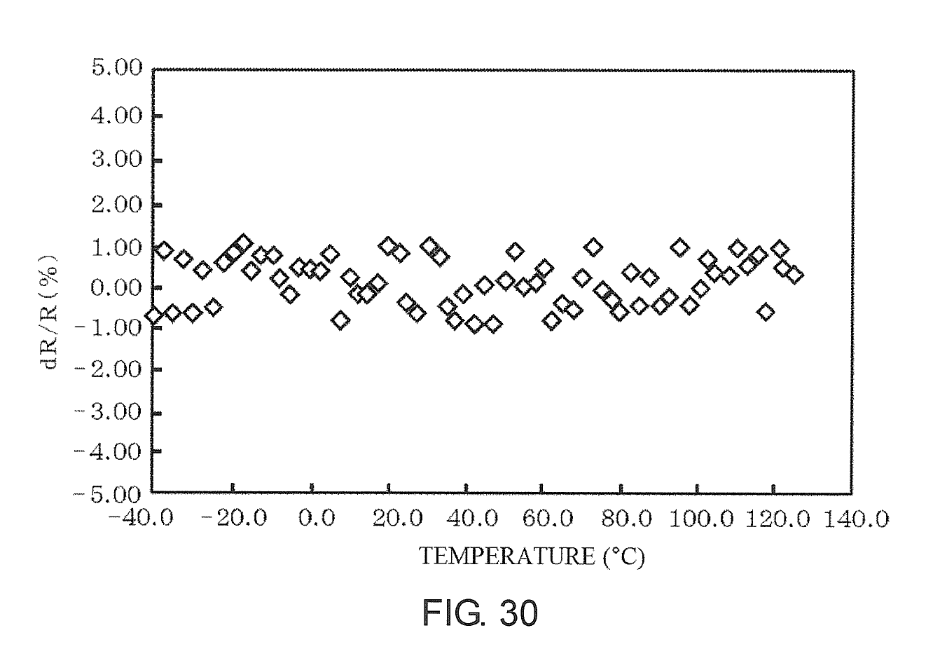

The measurement results of the temperature characteristic of the motional resistance are shown in FIG. 30. FIG. 30 is a graph where an average value of measurement data of the motional resistance is obtained and a difference between the average value and the measurement value (dR/R) is plotted. In the drawing, the horizontal axis indicates a temperature and the vertical axis indicates the difference. Consequently, a rapid frequency change was not confirmed and a generation of a dip was not observed as well. Measurement of an equivalent circuit constant resulted in C1=3.59 fF, R1=27Ω, and Q=61244. As described above, the extruding part is disposed near a boundary between the principal surface portion and the peripheral edge portion of the mesa-type crystal element across the whole circumference so as to surround the excitation electrode. Accordingly, it can be understood that a vibration different from the main vibration is reduced and energy can be confined to the principal surface portion, thus reducing generation of a dip.

One crystal resonator of this disclosure includes: a mesa-type crystal element with a principal surface portion and a peripheral edge portion that surrounds the principal surface portion and has smaller thickness than the principal surface portion; a pair of excitation electrodes formed at a principal surface portion on one surface side and a principal surface portion on another surface side of the crystal element, respectively; and at least one of an extruding part and a depressed part disposed at the crystal element configured to reduce a vibration different from a main vibration and confine energy to a principal surface portion. The extruding part and the depressed part are disposed near a boundary between a principal surface portion and a peripheral edge portion disposed at least one side of the principal surface portion on the one side of the surface and the principal surface portion on the other side of the surface. The extruding part and the depressed part are disposed across a whole circumference so as to surround an excitation electrode.

Another crystal resonator of this disclosure includes: a mesa-type crystal element with a principal surface portion and a peripheral edge portion that surrounds the principal surface portion and has smaller thickness than the principal surface portion; a pair of excitation electrodes formed at the principal surface portion on one surface side and the principal surface portion on an other surface side of the crystal element, respectively; and an extruding part disposed at an outer edge across a whole circumference of at least one of the excitation electrode on the one surface side and the excitation electrode on the other surface side of the crystal element, the extruding part being covered with an electrode film constituting the excitation electrode, the extruding part being constituted to reduce a vibration different from a main vibration and confine energy to the principal surface portion.

According to the embodiment, in the mesa-type crystal resonator with the principal surface portion and the peripheral edge portion that surrounds the principal surface portion and has smaller thickness than the principal surface portion and the excitation electrode is formed at the principal surface portion, at least one of the extruding part and the depressed part is formed near a boundary between the principal surface portion and the peripheral edge portion across the whole circumference so as to surround the excitation electrode. When the oscillating wave and the reflected wave excited at the crystal resonator are attempted to transmit to the region with the extruding part and the depressed part, the propagation direction is changed, the oscillating wave and the reflected cause diffused reflection, the oscillating wave about to propagate acts with one another, and the oscillating wave and the reflected wave gradually attenuate. Therefore, disposing the extruding part and the depressed part at the crystal element reduces a vibration different from the main vibration and confines energy to the principal surface portion, providing good vibration characteristic.

According to another embodiment of this disclosure, the extruding part is disposed at the outer edge of at least one of the excitation electrode on the one surface side and the excitation electrode on the other surface side of the crystal element across a whole circumference. The extruding part is covered with the electrode film constituting the excitation electrode. Therefore, disposing the extruding part reduces a vibration different from the main vibration and confines energy to the principal surface portion, providing good vibration characteristic.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A crystal resonator, comprising:
a mesa-type crystal element, having a principal surface portion and a peripheral edge portion, the peripheral edge portion surrounding the principal surface portion and the peripheral edge portion having a smaller thickness than the principal surface portion;
a pair of excitation electrodes, formed at the principal surface portion on one surface side and the principal surface portion on other surface side of the crystal element, respectively; and
a deformed portion, configured to reduce a vibration different from a main vibration, and the deformed portion confines energy to the principal surface portion.

2. The crystal resonator according to claim 1, wherein
the deformed portion includes at least one of an extruding part and a depressed part disposed at the crystal element to reduce a vibration different from a main vibration and confine energy to the principal surface portion, and
the extruding part and the depressed part are disposed near a boundary between the principal surface portion and the peripheral edge portion disposed at least one side of the principal surface portion on the one surface side and the principal surface portion on the other surface side, the extruding part and the depressed part being disposed across a whole circumference so as to surround the excitation electrode.

3. The crystal resonator according to claim 2, wherein
the extruding part and the depressed part are formed by etching a crystal element.

4. The crystal resonator according to claim 2, wherein
the extruding part and the depressed part are formed outside of the excitation electrode at the principal surface portion.

5. The crystal resonator according to claim 3, wherein
the extruding part and the depressed part are formed outside of the excitation electrode at the principal surface portion.

6. The crystal resonator according to claim 4, wherein
the extruding part and the depressed part are formed at a sidewall portion of the principal surface portion.

7. The crystal resonator according to claim 2, wherein
the extruding part and the depressed part are formed near a sidewall portion of the principal surface portion at the peripheral edge portion.

8. The crystal resonator according to claim 3, wherein
the extruding part and the depressed part are formed near a sidewall portion of the principal surface portion at the peripheral edge portion.

9. The crystal resonator according to claim 4, wherein
the extruding part and the depressed part are formed near a sidewall portion of the principal surface portion at the peripheral edge portion.

10. The crystal resonator according to claim 6, wherein
the extruding part and the depressed part are formed near a sidewall portion of the principal surface portion at the peripheral edge portion.

11. The crystal resonator according to claim 2, wherein
a wavelike-region where the extruding part and the depressed part are alternately arranged with one another at a crystal element is formed by disposing at least one of the extruding part and the depressed part at the crystal element.

12. The crystal resonator according to claim 3, wherein
a wavelike-region where the extruding part and the depressed part are alternately arranged with one another at a crystal element is formed by disposing at least one of the extruding part and the depressed part at the crystal element.

13. The crystal resonator according to claim 4, wherein
a wavelike-region where the extruding part and the depressed part are alternately arranged with one another at a crystal element is formed by disposing at least one of the extruding part and the depressed part at the crystal element.

14. The crystal resonator according to claim 6, wherein
a wavelike-region where the extruding part and the depressed part are alternately arranged with one another at a crystal element is formed by disposing at least one of the extruding part and the depressed part at the crystal element.

15. The crystal resonator according to claim 7, wherein
a wavelike-region where the extruding part and the depressed part are alternately arranged with one another at a crystal element is formed by disposing at least one of the extruding part and the depressed part at the crystal element.

16. The crystal resonator according to claim 1, wherein
the deformed portion includes an extruding part disposed at an outer edge across a whole circumference of at least one of the excitation electrode on the one surface side and the excitation electrode on the other surface side of the crystal element,
the extruding part being covered with an electrode film constituting the excitation electrode.

17. The crystal resonator according to claim 16, wherein
the extruding part is formed by laminating the electrode film.

18. The crystal resonator according to claim 16, wherein
the extruding part is positioned at least one of a surface portion of the principal surface portion, a sidewall portion of the principal surface portion, and a peripheral edge portion near the principal surface portion.

19. The crystal resonator according to claim 17, wherein
the extruding part is positioned at least one of a surface portion of the principal surface portion, a sidewall portion of the principal surface portion, and a peripheral edge portion near the principal surface portion.

20. The crystal resonator according to claim 16, wherein
the extruding part has a wavelike outer edge in plan view.
